(19) United States
(12) Patent Application Publication
(10) Pub. No.: US 2016/0029503 A1
(43) Pub. Date: Jan. 28, 2016

(54) REDUCING OR ELIMINATING BOARD-TO-BOARD CONNECTORS

(71) Applicant: Apple Inc., Cupertino, CA (US)

(72) Inventors: Anna-Katrina Shedletsky, Cupertino, CA (US); Fletcher R. Rothkopf, Cupertino, CA (US); Samuel B. Weiss, Cupertino, CA (US)

(21) Appl. No.: 14/641,321

(22) Filed: Mar. 7, 2015

Related U.S. Application Data
(60) Provisional application No. 62/027,416, filed on Jul. 22, 2014.

(51) Int. Cl. H05K 7/02

(52) U.S. Cl. CPC H05K 7/02

(57) ABSTRACT

Embodiments of the present disclosure provide a circuit board in which the need for board-to-board connectors is substantially reduced or eliminated. Specifically embodiments disclosed herein describe a flexible substrate for use with a computing device. A first module is surface mounted on a first side of the flexible substrate and a second module is surface mounted on a second side of the flexible substrate. A rigid circuit board is coupled to either the first side of the flexible substrate or the second side of the flexible substrate. Further, the flexible substrate is bendable such that at least one of the first module and the second module are positionable with respect to the rigid circuit board and with respect to the other of the first module and the second module.

### CROSS-REFERENCE TO RELATED APPLICATION

This application is a nonprovisional patent application of and claims the benefit to U.S. Provisional Patent Application No. 62/027,416, filed Jul. 22, 2014 and titled “Reducing or Eliminating Board-to-Board Connectors,” the disclosure of which is hereby incorporated herein by reference in its entirety.

### TECHNICAL FIELD

The present disclosure is directed to reducing or eliminating board-to-board connectors on circuit boards that are used in computing devices. Specifically, one or more embodiments of the present disclosure are directed to a flexible substrate or connector on which one or more components of the computing device may be directly placed.

### BACKGROUND

Computing devices typically have a variety of printed circuit boards (PCB) and other electronic components and modules that are connected to one another using various connectors. Typically, board-to-board connectors are used in making the connections. A board-to-board connector typically includes housing and a number of terminals that transmit a current or a signal between the printed circuit board and the electronic components. However, as the housing is typically made of an insulating material, such as plastic, the board-to-board connectors may take up valuable space on the printed circuit board. Further, when board-to-board connectors are placed on the printed circuit board, a minimum keep-out distance may be required between the board-to-board connector and other components or connectors.

It is with respect to these and other general considerations that embodiments have been made. Also, although relatively specific problems have been discussed, it should be understood that the embodiments should not be limited to solving the specific problems identified in the background.

### SUMMARY

This summary is provided to introduce a selection of concepts in a simplified form that are further described below in the Detailed Description section. This summary is not intended to identify key features or essential features of the claimed subject matter, nor is it intended to be used as an aid in determining the scope of the claimed subject matter.

Embodiments of the present disclosure provide a circuit board in which the need for board-to-board connectors is substantially reduced or eliminated. Specifically, embodiments disclosed herein describe a flexible substrate that is used to connect various components of a computing device to a main logic board and/or to each other. A first module may be coupled to a first side of the flexible substrate and a second module may be coupled to a second side of the flexible substrate. A rigid circuit board may also be coupled to either the first side of the flexible substrate or the second side of the flexible substrate. Further, the flexible substrate is bendable such that at least one of the first module and the second module are positionable with respect to the rigid circuit board and with respect to the other of the first module and the second module.

Also disclosed is a printed circuit board that includes a flexible substrate having one or more arms extending from a hub or central portion. A first component may be surface mounted to a first arm of the one or more arms of the flexible substrate. The first arm of the flexible substrate is bendable such that the first component is positionable in a housing of a computing device in one or more configurations.

Also disclosed is a method for connecting one or more modules of a computing device to a printed circuit board. The method includes coupling a first component to a first portion of a flexible substrate. The first portion of the flexible substrate may extend from a hub of the flexible substrate. The first portion of the flexible substrate is then manipulated, foldable or bendable such that the first component may be placed in a housing of a computing device in a first orientation of a plurality of orientations.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a side-view of a circuit board of computing device having a flexible substrate according to one or more embodiments of the present disclosure;

FIG. 2A-FIG. 2E illustrate various views of a circuit board having a flexible substrate being arranged into different orientations according to one or more embodiments of the present disclosure;

FIG. 3 illustrates a method for coupling components of a computing device to a circuit board according to one or more embodiments of the present disclosure; and

FIG. 4A-FIG. 4C illustrate exemplary computing devices in which the embodiments of the present disclosure may be used.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

Embodiments of the present disclosure are directed to reducing or eliminating board-to-board connectors on printed circuit boards. In certain embodiments, the circuit boards may be used for various computing devices including, but not limited to, mobile telephones, time keeping devices, health-monitoring devices, set-top boxes, glasses, personal digital assistants, tablets, personal and laptop computers, media playback devices, televisions, remote controls, and the like.

However, as computing devices become smaller, the space within a housing of any given device becomes more valuable and adding functionality in the form of electronic circuits, modules, components and the like becomes more difficult. In some instances, connectors (such as board-to-board connectors) consume a large percentage of the available space on a circuit board within a computing device. In other instances, these connectors may require a keep-out distance between the connector and another computing module. As such, both the size of the connector and the keep-out distance may consume valuable space on the circuit board.

Accordingly, embodiments of the present disclosure are directed to a flexible substrate that enables circuits, modules and other components of the computing device to be surface mounted directly (e.g., without requiring any separate electrical connector and using a hot bar process, Anisotropic Conductive Film (ACF) pads, and the like) on the flexible substrate. As will be described below, the flexible substrate is also able to be manipulated (e.g., foldable, bendable, twistable and the like) while still maintaining a connection with the modules and other components that are coupled to the flexible substrate. As such, the components, circuits and modules may be placed in various positions and/or orientations within a housing of the computing device. Further, because the components, circuits and modules do not need to be coupled to a surface of a main logic board of the computing device, these components, modules and circuits may be “tucked away” into various portions the housing that may otherwise be vacant, gone unused or underutilized.

For example, each of the components, circuits and modules of a computing device may be placed on various sides of the flexible substrate or a flexible circuit board. Further, a computing device may have any number of flexible substrates extending from a central circuit board. Each flexible substrate may be coupled to a variety of components, circuit, modules and/or connectors. In addition, each of the modules, connectors and circuits may be interconnected with traces, lines, wires and the like. As will be explained in detail below, the flexible substrate, while connected to the components, circuits, modules and connectors, may be folded or otherwise manipulated to fit within various spaces and geometries available in a housing of a computing device.

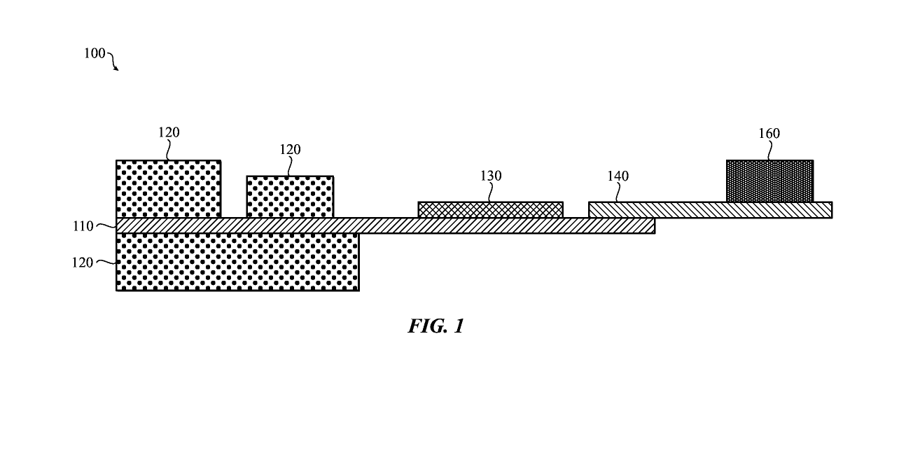

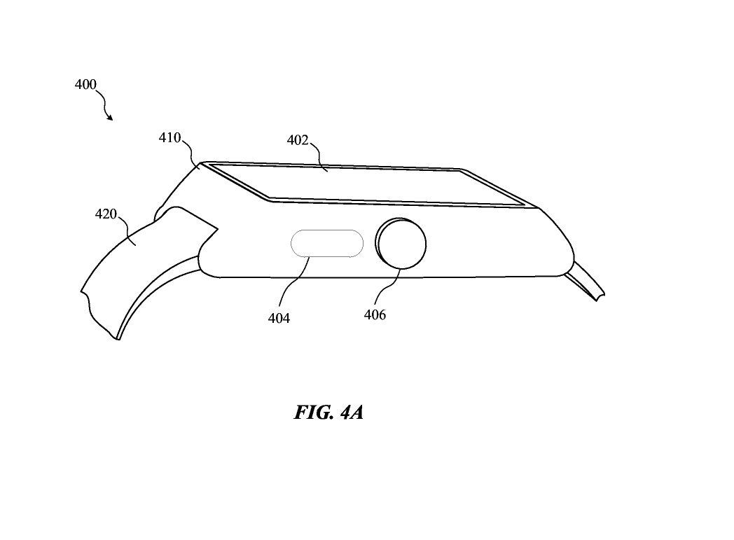

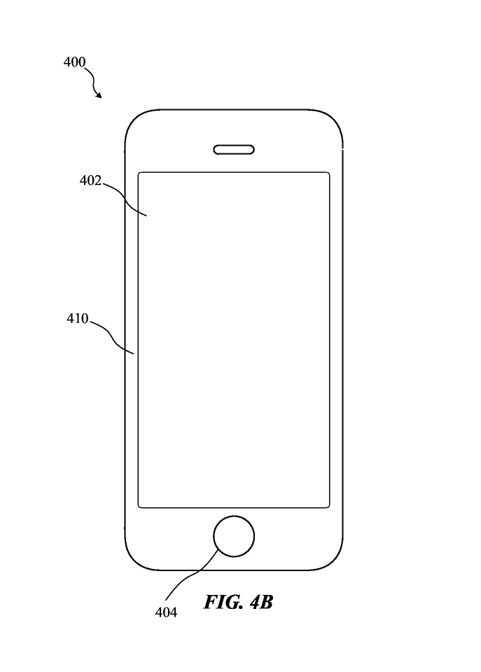

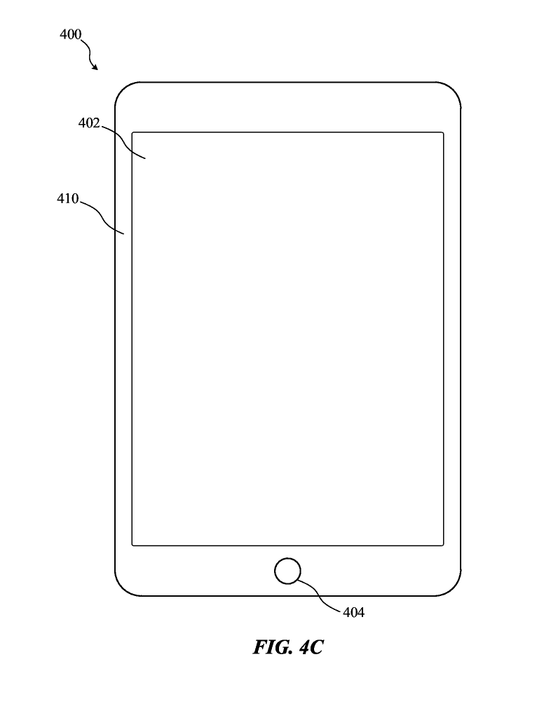

FIG. 1 illustrates a side-view of a circuit board 100 suitable for incorporation into a sample computing device according to one or more embodiments of the present disclosure. The circuit board may be used in a variety of computing devices including, but not limited to, the exemplary computing devices 400 shown and described with respect to FIG. 4A-FIG. 4C. The circuit board 100 may include a flexible substrate 110. The flexible substrate 110 may be bendable or otherwise manipulated such that one or more components or modules that have been coupled to the flexible substrate 110 may be placed in various locations within a housing of a computing device.

The flexible substrate 110 may include one or more modules 120. In certain embodiments, a molding and shielding process may be performed on the components or modules 120 that are part of the circuit board 100. For example, the molding process may be an over-molding process in which a molded layer is applied to at least a portion of the printed circuit board such that the mold forms around the components or modules 120.

As shown in FIG. 1, the flexible substrate 110 may be configured such that a first module may be surface mounted to a first side of the flexible substrate 110 and a second module may be surface mounted to a second side of the flexible substrate 110. The modules 120 may be integrated circuits, system on chip components, discrete components, connectors, or a combination thereof. In other embodiments, the modules 120 may be main logic boards, printed circuit boards and the like. Further, one or more components may be coupled to the main logic boards and the printed circuit boards that are coupled to the flexible substrate 110.

Although different modules, components and configurations are specifically mentioned, the flexible substrate 110 may be configured such that various combinations of components and modules may be surface mounted to the flexible substrate 110 without the need for a standard connector, such as, for example a board-to-board connector. For example, the flexible substrate 110 may be configured such that a first type of module (e.g., an integrated circuit and/or a connector) is surface mounted to a first side of the flexible substrate 110 and a second type of module (e.g., a main logic board) is surface mounted to a second side of the flexible substrate 110.

In another embodiment, the flexible substrate 110 may be placed, or sandwiched, between two main logic boards or other types of circuit boards. For example, a first a circuit board may be surface mounted or otherwise coupled to a first side of the flexible substrate 110 while a second circuit board is surface mounted or otherwise coupled to a second side of the flexible substrate 110. In other embodiments, the main logic board or circuit board may only be coupled to one side of the flexible substrate 110. In yet other embodiments, multiple flexible substrates 110 may extend from a single main logic board or from multiple circuit boards or main logic boards.

In another example, a first type of module and a second type of module may be surface mounted on a first side of the flexible substrate 110 and a third type of module may be surface mounted to a second side of the flexible substrate 110. For example, one or more discrete components and a system on chip component may be surface mounted on a first side of the flexible substrate 110 and a main logic board may be surface mounted to a second side of the flexible substrate. More specifically, a flexible substrate 110 may be coupled to, and extend from, the main logic board. Further, the various components and modules may be surface mounted to the portion of the flexible substrate 110 that extends from the main logic board. In yet another example, a main logic board and a system on chip component may be surface mounted to a first side of the flexible substrate 110 and various discrete components may be surface mounted to the second side of the flexible substrate 110.

In addition to the above, certain embodiments are directed to coupling a board-to-board connector to the flexible substrate 110. In such configurations, the functionality of the board-to-board connector may be utilized as if the board-to-board connector was coupled to the main logic board. However, because the board-to-board connector has been removed from the main logic board or other circuit board of the computing device, the minimum keep-out distance requirement between the board-to-board connector and the other modules is removed or reduced. As a result, the overall size of the circuit board of the computing device may be also reduced.

Although specific examples have been given, the flexible substrate 110, or multiple flexible substrates 110, may be coupled to various modules 120 in a variety of configurations. For example, two or more flexible substrates 110 may be coupled to a single main logic board. In another embodiment, a main logic board or circuit board may be surface mounted to a first side of a first portion of the flexible substrate and a second main logic board or circuit board (e.g., a satellite circuit board) may be surface mounted to a second portion of the first side (or the second side) of the flexible substrate 110. Further, additional flexible substrates 110 may extend from the main logic board and the satellite circuit board. As with other configurations disclosed herein, each flexible substrate 110, whether extending from a main logic board or a satellite circuit board, may have various components and modules coupled to one or more surfaces.

In another embodiment, multiple circuit boards may be coupled to a single flexible substrate 110, such as, for example, in a stacked configuration. For example, a first circuit board may be surface mounted to a first side of the flexible substrate 110 and a second circuit board may be surface mounted to a second side of the flexible substrate 110. Because the flexible substrate 110 is bendable, a distal end of the flexible substrate 110 may be folded over or otherwise positioned by either the first circuit board or the second circuit board. In some embodiments, the distal portion that is positioned over the first circuit board or second circuit board may be electrically coupled to the board and/or may be coupled to a third circuit board.

As discussed above, each of the components or modules 120 may be coupled to the flexible substrate 110 without the use of a connector, such as, for example, a board-to-board connector. Accordingly, in certain embodiments, the flexible substrate 110, or various portions of the flexible substrate 110, may include one or more ACF pads. These ACF pads may be used to couple the flexible substrate 110 to the various modules 120. Because the ACF pads are removed from the main logic board, connections and signals between and for the various modules 120 may be routed directly through the flexible substrate 110.

Although reworkability may be sacrificed in such implementations (as components may not easily be replaceable), valuable real-estate on the main logic board is increased. Alternatively, the overall size of the main logic board may be reduced. As the size of the main logic board is reduced, the size of other components, such as, for example, a battery, may increase. Although the use of ACF pads is specifically mentioned, in another embodiment, the modules 120 may be coupled to the flexible substrate using a hot-bar process, a pick and place process and the like.

Once the modules 120 have been coupled to the flexible substrate 110, the signals from each component may be routed through various conductive traces on the flexible substrate 110 to a desired destination, module, or circuit board. For example, the signals from one component may be routed through the conductive traces associated with the flexible substrate 110 directly to a main logic board. Likewise, various signals may be routed to another module or to another flexible substrate (e.g., flexible substrate 150) that is coupled to the flexible substrate 110. In some cases, a first flexible substrate may be configured to route a first type of signal to a first location or component while a second flexible substrate may be configured to route a second type of signal to either the first location or component and/or a second location or component. Further, a first flexible substrate may receive and/or route signals to various components or modules in a first direction while a second flexible substrate may receive and/or route signals to various components in a second direction.

In certain embodiments, the flexible substrate 110 may include a hub or a body portion. In addition, one or more arms may extend from the hub of the flexible substrate 110. As will be described below, once the components have been coupled to the arms of the flexible substrate 110, the arms may be bent, folded or otherwise manipulated such that the component or module that is coupled to the arm, as well as the arm of the flexible substrate 110, may be placed into the housing of the computing device at a desired location and/or orientation.

The arms, or other flexible substrates, may be surface mounted or otherwise coupled to the flexible substrate 110. For example, as shown in FIG. 1, flexible substrate 140 and flexible substrate 150 are surface mounted to the flexible substrate 110. Specifically as shown, flexible substrate 140 is surface mounted to a first portion of the flexible substrate 110 and flexible substrate 150 is surface mounted to a second portion of the flexible substrate 110. In some implementations, flexible substrate 140 and flexible substrate 150 may be coupled to flexible substrate 110 using ACF pads, a hot bar process and the like.

Although flexible substrate 140 and flexible substrate 150 are shown in FIG. 1 as being surface mounted to the same side of the flexible substrate 110, flexible substrate 140 may be surface mounted to the flexible substrate 110 on a different side than flexible substrate 150. Alternatively, flexible substrate 140 may be surface mounted to flexible substrate 150 and vice versa.

Each of the flexible substrates 140 and 150 may also include a module, for example, module 160. As with modules 120, the module 160 may be surface mounted to various sides of the flexible substrates 140 and 150. In alternative embodiments, the arm of the flexible substrate 110 may be connected (e.g., hot-barred, connected using ACF pads, etc.) to an arm of the module or to the module itself. For example, a display module may include ACF pads or other such connection mechanism. As such, the arm of the flexible substrate 110, 140 or 150 may be coupled directly to the ACF pads of the display module. In another embodiment, the display module may be directly coupled to the flexible substrate 110, 140 or 150 using a hot-bar process, ACF pads and the like. Although a display module is specifically mentioned, the module 160 may be a connector, a discrete component, a system on chip component, a circuit board and the like.

As discussed above, the flexible substrate 110 may be bendable or otherwise manipulated into a variety of configurations even when a module has been coupled to the flexible substrate 110. The flexible substrate 110 may also have a flexible portion and a rigid or non-flexible portion. In embodiments, modules may be placed on both the flexible portion of the flexible substrate 110 as well as the rigid portion of the flexible substrate 110.

For example, various components of a computing device may be more costly to replace than others or may have placement requirements in order to function properly. Some examples include a display module or movement sensitive components like gyroscopes, accelerometers and the like. As such, these components may be placed on the rigid portion of the flexible substrate 110. On the other hand, the less expensive modules or components, or those components or modules that are not movement sensitive, may be coupled to the flexible portion of the flexible substrate 110.

In certain embodiments, the rigidity of the rigid portion of the flexible substrate 110 may be attributed to the flexible substrate 110 being coupled to a main logic board or other circuit board. For example, when the flexible substrate 110 is coupled to a main logic board or a circuit board, the flexible substrate 110 may be laminated or otherwise coupled to the circuit board. In such configurations, and as discussed above, some modules 120 may be placed on the circuit board while other modules are placed directly on the flexible substrate 110.

In embodiments, the size of the flexible substrate 110 may be based, at least in part, on the size of the housing of the computing device. Further, the size of the flexible substrate 110 may be based on the intended use of the computing device, the number of components required by the computing device or the number of main logic board and/or circuit boards used by the computing device.

As the components or modules 120 may be surface mounted or otherwise coupled directly to the flexible substrate 110, replacement of individual components may be difficult. For example, once a component or module is surface mounted to the flexible connector, that component or module may not be easily replaceable. Accordingly, in certain embodiments, the flexible substrate 110 may be configured in such a way as to enable certain components to be replaceable while other components may need to be sacrificed.

For example, components that are costly to replace may be placed on a first portion of a flexible substrate such as flexible substrate 110 while components or modules that are less costly to replace may be coupled to another flexible substrate, such as flexible substrate 140. Using this configuration, if a non-expensive component needs to be replaced on flexible substrate 140, the entire flexible substrate 140, or a portion of the flexible substrate 140, may be removed. A replacement flexible substrate that includes the same or similar modules and components may then be coupled to flexible substrate 110. Likewise, if the costly component or module needs to be replaced, that component or module, and/or the flexible substrate 110, may be removed and replaced.

In embodiments in which the flexible substrate 110 includes a rigid portion, the modules or components on the rigid portion may be removable and replaceable while the components of the flexible substrate 110 are not. For example, if a component or module on an arm of the flexible substrate is defective, that arm of the flexible substrate 110, along with any and/or all components or modules 120 on the arm, may be removed and replaced with a new arm portion having new components or modules 120. Alternatively, the modules or components on the rigid portion of the flexible substrate may be removed and replaced individually.

Although some components and modules may not be easily replaceable, embodiments described herein increase the ease of manufacturing. For example, because the connectors may be placed on various arms of the flexible substrate 110 and at various locations on the flexible substrate, these connectors may be accessible at various times during the manufacturing or building process of the computing device.

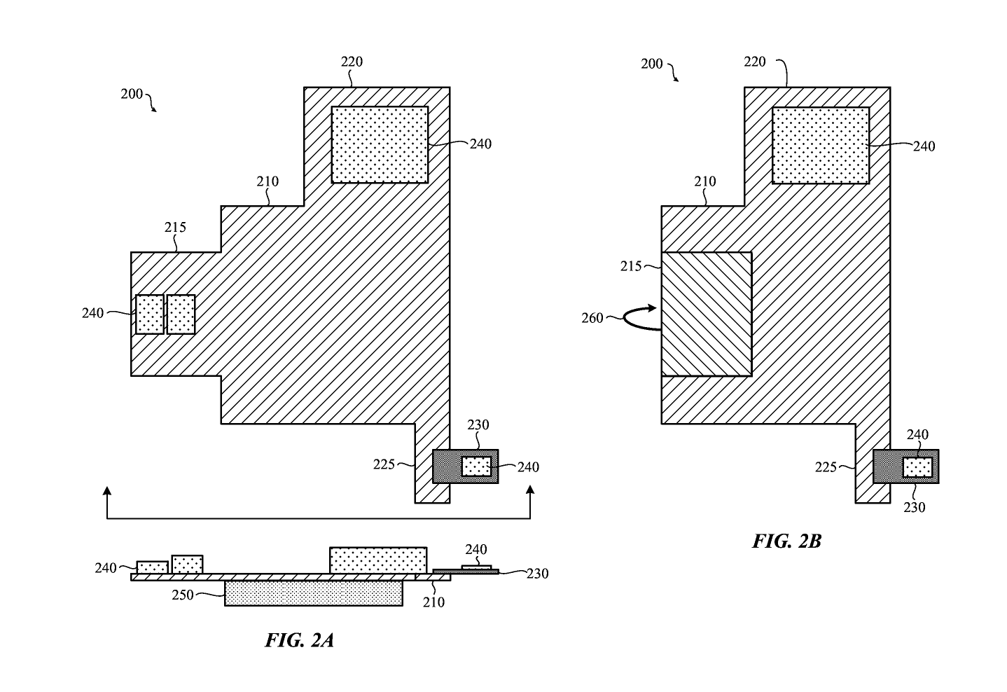

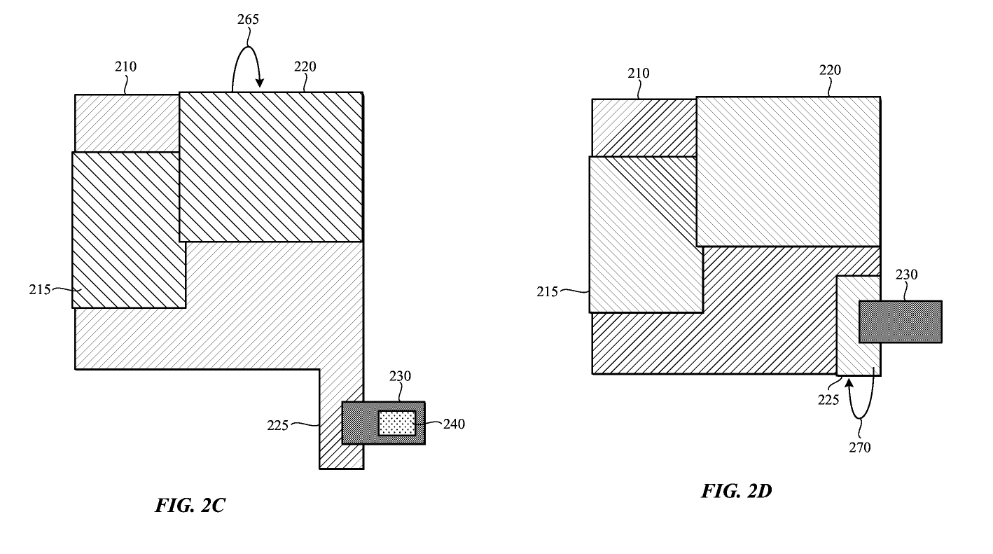

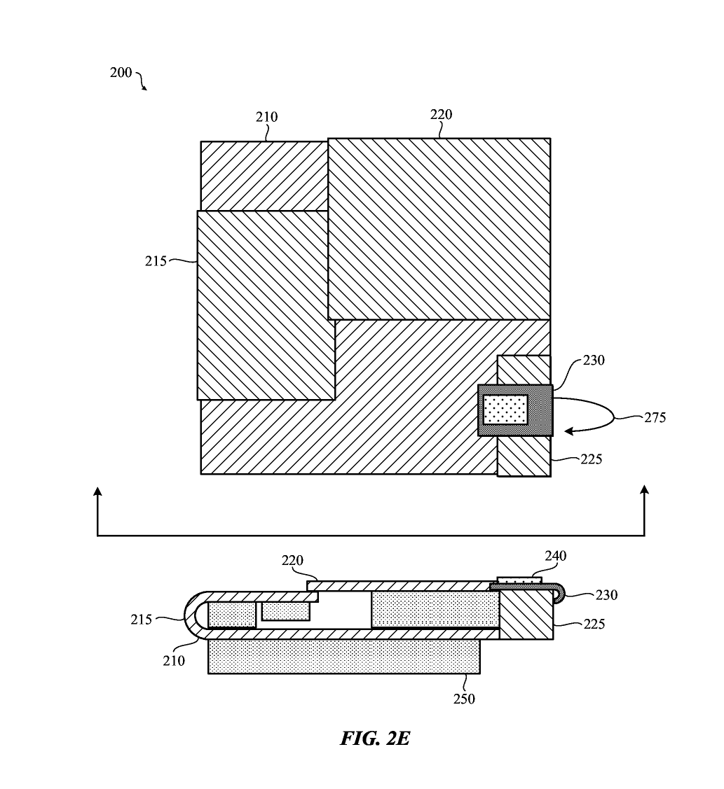

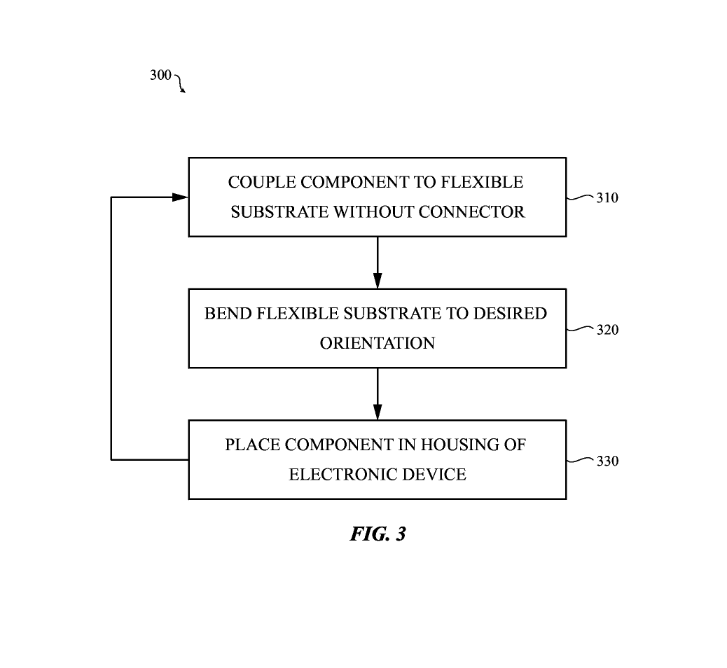

FIG. 2A-FIG. 2E illustrate various views of a circuit board 200 having a flexible substrate 210 that is arranged into different orientations according to one or more embodiments of the present disclosure. Embodiments described with respect to FIG. 2A-FIG. 2E may be used with the embodiments described above with respect to FIG. 1.

FIG. 2A illustrates a circuit board 200, and a corresponding side view of the circuit board 200, according to one or more embodiments of the present disclosure. The circuit board 200 may include a flexible substrate 210 and one or more modules 240. The modules 240 may be integrated circuits, system on chip components, discrete components, connectors, main logic boards and the like.

As shown in FIG. 2A, the one or more modules 240 may be surface mounted to one or more sides of the flexible substrate 210. Specifically, a first module 240 may be surface mounted to a first side of the flexible substrate 210 and a second module 250 may be mounted on a second side of the flexible substrate. In certain embodiments, the second module 250 may be a main logic board or other circuit board. In such implementations, the flexible substrate may be laminated to or otherwise coupled to the second module 250. Accordingly, at least a portion of the flexible substrate 210 may be rigid. In embodiments where the second module 250 is a main logic board or other circuit board, components or modules that may require a more stable base layer (e.g., accelerometers, gyroscopes and the like) may be placed on the second module 250 or on a rigid portion of the flexible substrate 210.

The flexible substrate 210 may also include one or more arms. For example, as shown in FIG. 2A, the flexible substrate may include a hub or body portion and various arms 215, 220, 225 and 230 may extend from the hub. Although a square shaped hub is specifically shown, the hub of the flexible substrate 210 may be in any shape or size. Further, although four arms 215, 220, 225 and 230 are shown extending from the hub of the flexible substrate 210, the flexible substrate 210 may have any number of arms extending therefrom.

Each of the arms 215, 220 and 225 may be integral with (e.g., an original part of) the flexible substrate 210. In another embodiment, one or more arms, such as, for example arm 230, may be electrically coupled or surface mounted to the flexible substrate 210. Further, as will be described below, each of the arms 215, 220, 225 and 230 may be folded or otherwise manipulated such that the modules 240 on the arms 215, 220, 225 and 230 may be placed in a particular or desired orientation with respect to the other arms and modules 240 of the circuit board 200.

FIG. 2B illustrates the circuit board 200 in which a first arm 215 of the flexible substrate 210 has been folded or otherwise manipulated with respect to the circuit board 200 according to one or more embodiments of the present disclosure. For example, as shown in FIG. 2B, the arm 215 has been manipulated in the direction of arrow 260 such that the top surface of the arm 215 (e.g., the surface on which the modules 240 have been placed) is facing the hub of the flexible substrate 210. Although arm 215 is shown as being bending inward toward the hub of the flexible substrate 210, the arm 215 may also be folded in the opposite direction.

FIG. 2C illustrates the circuit board 200 in which a second arm 220 of the flexible substrate 210 has been folded or otherwise manipulated with respect to the circuit board 200 according to one or more embodiments of the present disclosure. As with arm 215, arm 220 has been folded or manipulated in the direction of arrow 265 such that the module on the arm 220 is positioned between the hub of the flexible substrate 210 and the arm 220. However, in certain embodiments, the arm 220 may be folded in the opposite direction.

Further, in certain embodiments, a first arm, such as arm 215, may be folded in a first direction, and a second arm, such as arm 220 may be folded in a second direction. For example, the first arm may be folded toward the hub of the flexible substrate 210 and the second arm 220 may be folded away from the hub of the flexible substrate 210.

As shown in FIG. 2C, the arms 215 and 220 may overlap when the arms have been folded or otherwise manipulated. In other embodiments the arms do not overlap. Further, although not shown, a component or module may be disposed on the back side (e.g., the side that is exposed after the folding or manipulation) of one or more of the arms 215, 220, 225 and 230.

As with FIG. 2B and FIG. 2C, FIG. 2D illustrates the circuit board 200 when the third arm 225 is folded or otherwise manipulated in the direction indicated by arrow 270.

FIG. 2E illustrates the circuit board 200, and a corresponding side view, when each of the arms associated with the flexible substrate 210 have been folded or otherwise manipulated in the manner described above. As shown in FIG. 2E, each of the modules 240 on the flexible substrate 210 are manipulated such that they fit within a desired shape or dimension. Further, although each of the arms is shown in a folded configuration, in certain embodiments, some of the arms may be folded while other arms, or other such extensions of the flexible substrate 210 may be in an extended or semi-folded configuration.

FIG. 3 illustrates a method 300 for connecting modules to a flexible substrate according to one or more embodiments of the present disclosure. In certain embodiments, the method 300 may be used to create the circuit board 100 shown and described with respect to FIG. 1 and the circuit board 200 shown and described above with respect to FIG. 2.

Method 300 begins when a component or module is coupled to a flexible substrate. In embodiments, the component or module is coupled to the flexible substrate without the use of a connector such as, for example, a board-to-board connector. As such, the component or module is coupled to the flexible substrate using ACF pads, a hot-bar process, a surface mounting process and the like.

In addition, a module may be surface mounted to various sides of the flexible substrate. For example, a first module may be surface mounted to a first side of the flexible substrate and a second module may be surface mounted to a second side of the flexible substrate. In embodiments, a second flexible substrate may be surface mounted to the original flexible substrate. In such configurations, one or more modules may also be surface mounted on each side of the second flexible substrate. As discussed above, the modules that are surface mounted on the flexible substrates may be integrated circuits, system on chip components, discrete components, connectors, main logic boards and the like.

Once the module has been coupled to the flexible substrate, flow proceeds to operation 320 in which the flexible substrate is manipulated into a desired orientation. In embodiments, the desired orientation may be an orientation in which the module or component that is coupled to the flexible substrate is moved from a position off the main logic board and into another area of the housing. Such a configuration may maximize volume within the housing.

For example, if an area in the housing was previously unused because of the shape, size or configuration of the main logic board, or because of various components and connections on the main logic board could not fit or otherwise be connected in the unused space, a module may be coupled to the flexible substrate and the flexible substrate and the module may subsequently be placed within the housing to occupy the previously unused space. Further, because various modules and connectors are moved off of the main logic board, the overall size of the main logic board may be reduced as there is no required keep-out distance between the various connectors and modules on the main logic board.

Flow then proceeds to operation 330 in which the component is placed in the housing of the computing device. As discussed above, in certain embodiments, the flexible substrate may be manipulated such that a component may be placed in an area within the housing of the computing device that was previously unused or not used efficiently. In another embodiment, the components or modules may be arranged such as described above with respect to FIG. 2A-FIG. 2E.

For example, if the flexible substrate included a number of arms that extend from a hub of the flexible substrate, each arm may be manipulated such that the components on the flexible substrate may be arranged in the housing of the computing device to maximize volume within the housing of the computing device.

FIG. 4A-FIG. 4C illustrate exemplary computing devices 400 that may be used with the various embodiments described herein. In some cases, the computing device 400 may be a small form factor device such as a wearable computing device. As such, the small form factor device may have a limited amount of space in the housing 410. As such, the circuit board 100 may be of particular use in such a small form factor device.

For example, as shown in FIG. 4A, the computing device 400 may be configured to be attached to the wrist of a user using a band 420. Although a wearable computing device is specifically mentioned and shown with respect to FIG. 4A, the embodiments disclosed herein may be used with any number of computing devices. For example, the computing device 400 may be a mobile phone (such as shown in FIG. 4B), a tablet computer (such as shown in FIG. 4C), a laptop computer or other portable computing device, a time keeping device, a pair of computerized glasses, a navigation device, a sports device, a portable music player, a health device, a medical device and the like. As such, similar reference number may be used in each of FIG. 4A-FIG. 4C.

Referring back to FIG. 4A-FIG. 4C, the computing device 400 may include a display 402 that is integrated with the case of the device body (or housing) 410. The display 402 may be formed from a liquid crystal display (LCD), organic light emitting diode (OLED) display, organic electroluminescence (OEL) display, or other type of display. The display 402 may be used to present visual information to a user and may be operated in accordance with one or more display modes or the software applications being executed by or on the computing device 400.

By way of example, the display 402 may present a variety of visual information to a user. This visual information may correspond to applications that are being executed by the computing device 400 or by the various components or modules contained within the computing device 400, such as, for example, modules 120 (FIG. 1).

In some instances, a touch sensor (not shown) may be integrated with the display 402 or other element of the device 400. The touch sensor may be formed from one or more capacitive sensor electrodes or nodes that are configured to detect the presence and/or location of an object or the user's finger that is touching the surface of the display 402.

As also shown in FIG. 4A, the computing device 400 also includes one or more buttons 404 and a crown 406 that may be used to receive user input. Although not shown, the device body 410 may also integrate other types of user input devices or modules, including for example, dials, slides, roller balls or similar input devices or mechanisms.

Further, the computing device 400 may include other components not shown or described above. For example, the computing device 400 may include a keyboard or other input mechanism. Additionally, the computing device 400 may include one or more components that enable the computing device 400 to connect to the internet and/or access one or more remote databases or storage devices. The computing device 400 may also enable communication over wireless media such as acoustic, radio frequency (RF), near field communication, infrared, and other wireless media mediums. Such communication channels may enable the computing device 400 to remotely connect and communicate with one or more additional devices such as, for example, a laptop computer, tablet computer, mobile telephone, personal digital assistant, portable music player, speakers and/or headphones and the like.

The description and illustration of one or more embodiments provided in this disclosure are not intended to limit or restrict the scope of the present disclosure as claimed. The embodiments, examples, and details provided in this disclosure are considered sufficient to convey possession and enable others to make and use the best mode of the claimed embodiments. Additionally, the claimed embodiments should not be construed as being limited to any embodiment, example, or detail provided above. Regardless of whether shown and described in combination or separately, the various features, including structural features and methodological features, are intended to be selectively included, omitted or rearranged to produce an embodiment with a particular set of features. Having been provided with the description and illustration of the present application, one skilled in the art may envision variations, modifications, and alternate embodiments falling within the spirit of the broader aspects of the embodiments described herein that do not depart from the broader scope of the claimed embodiments.

We claim:

1. A computing device comprising:
a first module surface mounted on a first side of a flexible substrate;
a second module surface mounted on a second side of the flexible substrate; and
a rigid circuit board mounted on either the first side of the flexible substrate or the second side of the flexible substrate, wherein the flexible substrate is bendable such that the first module is positionable with respect to the rigid circuit board and the second module.

2. The computing device of claim 1, wherein at least one of the first module and the second module are system component modules.

3. The computing device of claim 1, wherein at least one of the first module and the second module are discrete components of the computing device.

4. The computing device of claim 1, wherein the flexible substrate is sandwiched between the first module and the second module.

5. The computing device of claim 1, wherein the first module and the second module are arranged in a stacked configuration.

6. The computing device of claim 1, further comprising at least one additional flexible substrate, wherein the at least one additional flexible substrate is surface mounted to one of the first side of the flexible substrate and the second side of the flexible substrate.

7. The computing device of claim 6, wherein the at least one additional flexible substrate is surface mounted to either the first side of the flexible substrate and the second side of the flexible substrate without using a connector.

8. The computing device of claim 1, wherein:
the flexible substrate comprises at least one arm extending away from a body of the flexible substrate; and
the at least one arm is configured to be connected to a third module.

9. The computing device of claim 8, wherein the at least one arm comprises a board-to-board connector.

10. The computing device of claim 8, wherein the third module is surface mounted to a first side of the at least one arm without using a board-to-board connector.

11. A printed circuit board comprising:
a flexible substrate having one or more arms extending therefrom;
a first component surface mounted to a first arm of the one or more arms of the flexible substrate without a board-to-board connector; and
a second component surface mounted to a second arm of the one or more arms of the flexible substrate without a board-to-board connector;
wherein the first arm of the flexible substrate and the second arm of the flexible substrate are bendable such that each of the first component and the second component are positionable in a housing of a computing device in one or more configurations.

12. The printed circuit board of claim 11, wherein at least one of the first arm and the second arm have a third component surface mounted thereon.

13. The printed circuit board of claim 12, wherein the third component is surface mounted on a surface that is opposite from either the first component or the second component.

14. The printed circuit board of claim 11, wherein the second arm of the flexible substrate is foldable with respect to the first arm of the flexible substrate.

15. The printed circuit board of claim 11, further comprising a second connector surface mounted on the flexible substrate.

16. The printed circuit board of claim 11, further comprising a board-to-board connector surface mounted on the flexible substrate.

17. A method for connecting one or more modules to a printed circuit board, the method comprising:
surface mounting a first component to a first portion of a flexible substrate, wherein the first portion of the flexible substrate extends from a hub of the flexible substrate;
surface mounting a second component to a second portion of the flexible substrate, wherein the second portion of the flexible substrate extends from the hub of the flexible substrate;
bending the first portion of the flexible substrate to place the first component in a housing of a computing device in a first orientation; and
bending the second portion of the flexible substrate to place the second component in the housing of the computing device in a second orientation.

18. The method of claim 17, wherein at least a portion of the second component is stacked on top of the at least a portion of the first component when the second component is placed within the housing of the computing device.

19. The method of claim 17, further comprising surface mounting a board-to-board connector on one of the first portion of the flexible substrate and the second portion of the flexible substrates.

20. The method of claim 17, further comprising surface mounting a second flexible substrate to the flexible substrate.
